(19) United States
(12) Patent Application Publication
(10) Pub. No.: US 2008/0230259 A1
(43) Pub. Date: Sep. 25, 2008

(54) Method and Structure for Implementing Control of Mechanical Flexibility With Variable Pitch Meshed Reference Planes Yielding Nearly Constant Signal Impedance

(76) Inventors: Roger Allen Booth Jr., Wappingers Falls, NY (US); Matthew Stephen Doyle, Rochester, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/689,641

(22) Filed: Mar. 22, 2007

(51) Int. Cl. H05K 1/02; H05K 1/11

(52) U.S. Cl. 174/254; 174/257; 361/749; 427/96.1

(57) ABSTRACT

A method and structure are provided for implementing flexible circuits of various electronic packages and circuit applications. A meshed reference plane includes a variable mesh pitch arranged for control of mechanical flexibility. A dielectric core separates a signal layer from the variable pitch meshed reference plane. An electrically conductive coating covers the surface of the variable pitch meshed reference plane yielding substantially constant signal impedance for the signal layer.

### FIELD OF THE INVENTION

The present invention relates generally to the data processing field, and more particularly, relates to a method and structure for implementing control of mechanical flexibility including variable pitch meshed reference planes yielding substantially constant signal impedance in flexible circuits of various electronic packages and circuit applications.

### DESCRIPTION OF THE RELATED ART

Flexible circuits or flex circuits are used in various electronic packages and circuit applications. One significant contribution of flexible circuits is their ability to meet stringent mechanical flexibility requirements. Flex circuits are generally applied to all static and dynamic interconnects that cannot be accomplished through rigid card constructs. Through the use of flexible dielectric and bonding mediums, combined with meshed reference planes, flex circuits can provide dynamic, high-speed interconnects.

Both first-level packaging and flexible circuit technology often utilize cross-hatched or mesh copper ground and power reference planes for reference current-flow distribution and to provide mechanical flexibility.

Signals with meshed reference ground planes can see different impedances based upon pitch of the mesh, and/or the direction of the signal wire with respect to the direction of the mesh wire. The impedance differences can lead to various problems, such as cross-talk, electromagnetic compatibility (EMC) issues, reflection, and difficult wiring constraints. On some flex circuit designs, the problems associated with a meshed grid reference necessitate the use of a solid plane of copper, which limits flexibility or inhibits the achievement of flexibility requirements in the card.

Ground rules typically require a fixed pitch mesh for an entire design, meaning that the design engineer must make trade-offs between flexibility of the final card and signaling quality. For example, not the entire area of a power plane carries the same amount of current. It may be desirable to have a tighter mesh between power pins on a connector and a module, and a wider mesh in other areas of the plane. However the signaling impedance on signal layers referencing such a power plane would suffer discontinuities if a circuit was designed like this.

Also instances occur when one power plane carries significantly less current than an adjacent power plane. It would be desirable to use different mesh pitches for the two different planes, but this would result in significant impedance discontinuities for the wiring layer between these power planes.

U.S. Pat. No. 5,334,800 issued Aug. 2, 1994 shows one example of making a flexible circuit with a mesh ground plane. The flexible, shielded circuit board includes a number of electrical conductors disposed in a substrate, substantially parallel to opposing surfaces of the substrate. Electrical shield layers in the form of a mesh or grid are disposed on the substrate surfaces and are preferably formed by screen-printing a conductive layer on each side of the substrate. A repeating pattern of shield conductors, shield conductor vertices, and voids in the shield layer through which the substrate is exposed is thus created on either side of the substrate.

U.S. patent application Ser. No. 11/008,812, to one of the present inventors Matthew Stephen Doyle, filed Dec. 9, 2004, and assigned to the present assignee, discloses a method and apparatus for implementing characteristic impedance discontinuity reduction in customized high-speed flexible circuit applications. A curved artwork region is selected and selected cells are scanned. An area on opposite sides of a signal wire within each cell is determined. The identified areas are compared using a user defined delta value. If the compared areas differ greater than the user defined delta value, then a coordinate change is computed for moving the signal wire to reduce characteristic impedance discontinuity.

U.S. Pat. No. 5,296,651 discloses a flexible circuit suitable for high-density applications and having a long flexural life. A thin film metallic ground plane electrically shields the conductor traces in the flexible circuit and attempts to reduce in-plane cross-talk between conductor traces without reducing the flexibility or the flexural life of the flexible circuit. The ground plane deposited on a dielectric substrate includes a pattern of holes formed in ground plane for adding flexibility, while also allowing Z-axis cross-talk.

U.S. patent application Ser. No. 11/250,043, to the present inventors Roger Allen Booth Jr. and Matthew Stephen Doyle, filed Oct. 13, 2005, and assigned to the present assignee, discloses a method and mesh reference applications are provided for implementing Z-axis cross-talk reduction. A mesh reference plane including a grid of mesh traces is formed with the mesh traces having selected thickness and width dimensions effective for reference current-flow distribution. An electrically conductive coating is deposited to fill the mesh electrical holes in the mesh reference plane to reduce cross-talk, substantially without affecting mechanical flexibility.

A need exists for an effective mechanism that allows for variable mesh pitch within a meshed reference plane in flexible circuits applications.

### SUMMARY OF THE INVENTION

A principal aspect of the present invention is to provide a method and structure for implementing control of mechanical flexibility including variable pitch meshed reference planes yielding substantially constant signal impedance in flexible circuits of various electronic packages and circuit applications. Other important aspects of the present invention are to provide such method and structure for implementing flexible circuits substantially without negative effect and that overcome many of the disadvantages of prior art arrangements.

In brief, a method and structure are provided for implementing flexible circuits of various electronic packages and circuit applications. A meshed reference plane includes a variable mesh pitch arranged for control of mechanical flexibility. A dielectric core separates a signal layer from the variable pitch meshed reference plane. An electrically conductive coating covers the surface of the variable pitch meshed reference plane yielding substantially constant signal impedance for the signal layer. In accordance with features of the invention, the meshed reference plane includes a dense mesh path for carrying high current, and a less dense mesh for small current flow providing enhanced flexibility for the flexible circuit. The meshed reference plane includes a wide mesh pitch generally centrally located with increasing mesh pitch to control of mechanical flexibility, providing enhanced flexibility near the center of the flexible circuit.

In accordance with features of the invention, the electrically conductive coating is a thin copper coating and does not impact mechanical flexibility. thickness of the electrically conductive coating is substantially less than the thickness of the mesh traces of the mesh reference plane, for example, about 1/25 of the thickness of the mesh traces. The electrically conductive coating is formed, for example, of a copper thin film. The electrically conductive coating has a thickness of about one micrometer (10⁻⁶ meter). The electrically conductive coating is deposited using a sputtering process, such as a vacuum sputtering deposition process.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1 and 2 are top views illustrating exemplary flexible circuit structures in accordance with the preferred embodiments; and

FIGS. 3, 4, 5, and 6 are side views not to scale illustrating exemplary steps of a method for forming a flexible circuit structure in accordance with the preferred embodiment.

### DETAILED DESCRIPTION OF THE PREFERRED EMBODIMENTS

In accordance with features of the invention, a reference plane is provided which behaves electrically almost like a solid reference, while behaving mechanically like a meshed reference. That is, the reference plane is highly flexible, yet the wiring impedance is nearly constant regardless of mesh pitch and direction of the wire with respect to the mesh. Additionally, this invention allows the designer to control the mechanical flexibility of the circuit through layout of the power planes.

A structure of the invention is a meshed reference plane with a very thin conducting layer deposited, typically deposited by sputtering, over the mesh before lamination to the next core assembly. In accordance with features of the invention, significant advantages are provided over a fixed pitch mesh, or a standard solid reference in a flex circuit application. Primarily, the advantage of this invention is that it enables a significant improvement in wireability of flexible circuits or electronic packages with meshed reference planes. High performance signaling can be achieved on prior art flex circuits, but at the expense of difficult wiring constraints and circuit flexibility. This invention can allow even faster signaling than prior art circuits, while at the same time easing wiring constraints.

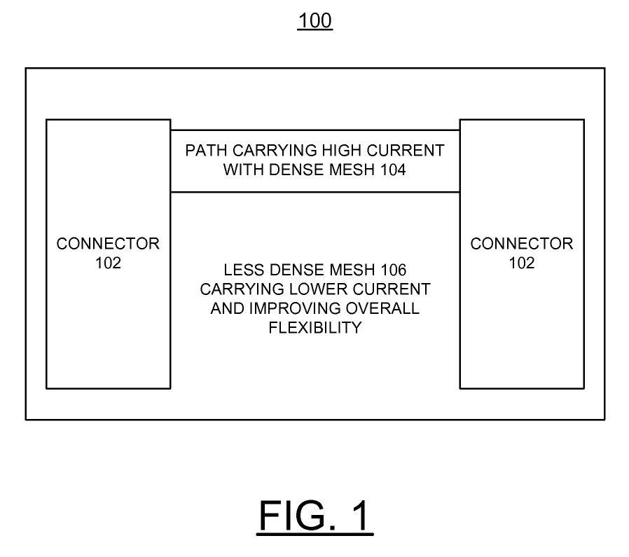

In accordance with features of the invention, improved connector wiring contact reliability is enabled resulting from the method of the invention to control mechanical flexing away from delicate pads or via arrays near connector pins and pads. Having reference now to the drawings, in FIG. 1, there is shown an exemplary flexible circuit structure generally designated by the reference character 100 in accordance with the preferred embodiment.

As shown in FIG. 1, flexible circuit structure 100 includes a pair of connectors 102 connected by a first reference plane path carrying high current with a dense mesh 104. Flexible circuit structure 100 includes a less dense reference plane mesh 106 surrounding the dense mesh 104. The less dense mesh 106 carries lower current and provides improved overall flexibility.

The area of dense mesh 104 has a predefined density and size to provide high current carrying capabilities, while overall flexibility is maintained by selectively providing areas of less dense mesh 106.

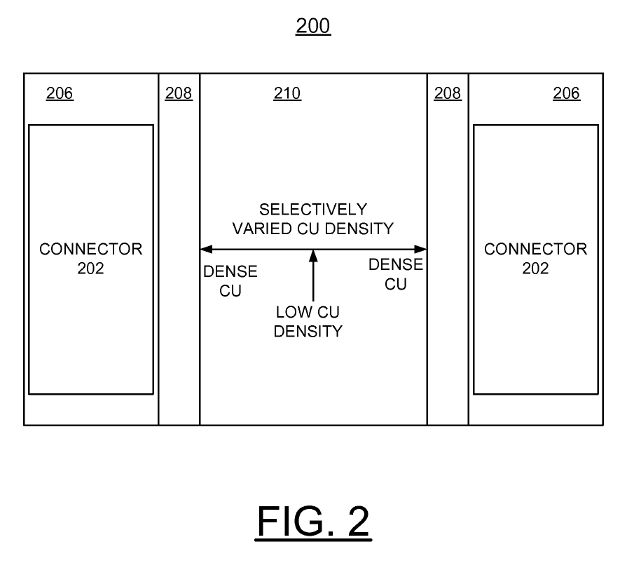

Referring also to FIG. 2, there is shown an exemplary flexible circuit structure generally designated by the reference character 100 in accordance with the preferred embodiment.

As shown in FIG. 2, flexible circuit structure 200 includes a pair of connectors 202 located at opposite ends 206 of the flexible circuit structure.

Flexible circuit structure 200 includes a respective first area 208 near the respective connectors 202 having increasing mesh pitch to allow greater flexibility towards a center of the flexible circuit structure. A generally central area 210 of the flexible circuit structure 200 includes a variable pitch meshed reference plane with a centrally located lowest copper density provided with a wide mesh pitch for most flexibility and dense copper density near the first area 208.

It should be understood that area of variable mesh pitch is not limited to the generally central area 210 of the flexible circuit structure 200. The respective first area 208 near the respective connectors 202 advantageously can include a variable mesh pitch.

In accordance with features of the invention, manipulation of the meshed ground reference plane 206, 208, 210 is arranged to persuade or move the area of dynamic bending away from the fragile connector-to-flex boundaries. Critically, the present invention allows this change to the meshed ground reference plane without impedance discontinuities through the use of a very thin electrically conductive coating, advantageously formed by copper sputtering.

In accordance with features of the invention, the varied mesh reference plane pitch or density is enabled within areas of the flexible circuit structures 100, 200 that are used as a fat-wire for DC, while eliminating the problem of impedance Zo discontinuity which would normally be caused in prior art arrangements.

In accordance with features of the invention, the variable pitch meshed reference planes 104, 106 of the flexible circuit structure 100 and the variable pitch meshed reference planes 208, 210 of the flexible circuit structure 200 include a very thin copper coating that substantially eliminates all impedance discontinuities in the flexible circuit structures. The thin electrically conductive coating does not impact mechanical flexibility. The thickness of the electrically conductive coating is substantially less than the thickness of the mesh traces of the mesh reference plane, for example, about 1/25 of the thickness of the mesh traces. The electrically conductive coating is formed, for example, of a copper thin film. The electrically conductive coating has a thickness of about one micrometer (10⁻⁶ meter). The electrically conductive coating is deposited using a sputtering process, such as a vacuum sputtering deposition process.

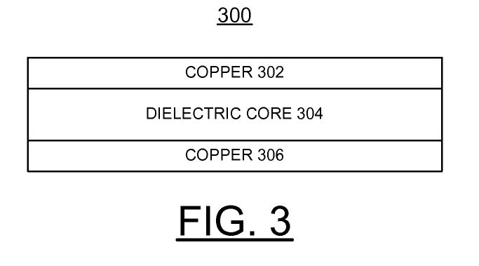

Referring to FIGS. 3, 4, 5, and 6, there are side views not to scale illustrating exemplary steps of a method for forming flexible circuit structures in accordance with the preferred embodiment.

Referring to FIG. 3, an initial step generally designated by the reference character 300 of the fabrication sequence is shown. The process begins with a first copper sheet 302 carried by a dielectric layer or dielectric core 304 and an opposed second copper sheet 306.

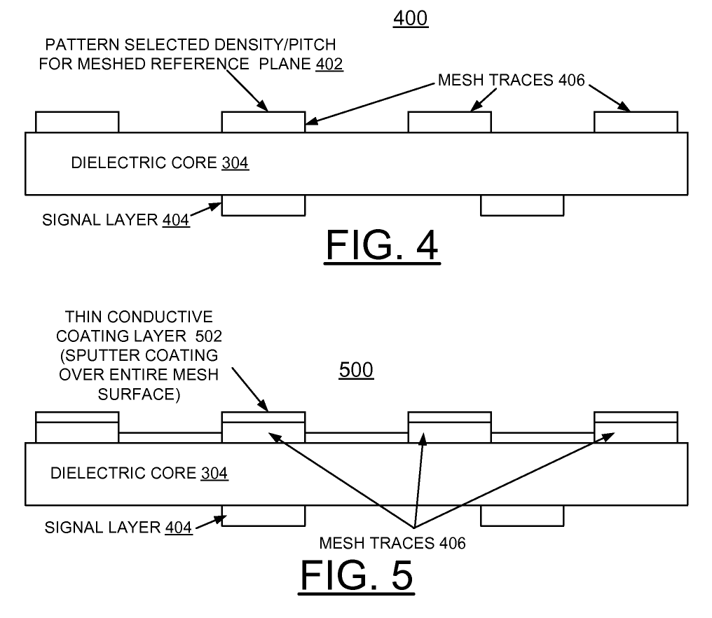

Referring to FIG. 4, a next step generally designated by the reference character 400 of the fabrication sequence is shown to pattern a mesh having variable of selected density/pitch for the meshed reference plane 402 from the copper layer 302 and a signal layer 402 from the copper layer 306. A variable density meshed reference plane 402 is patterned to define a grid of mesh lines or traces 406 having selected thickness and width dimensions effective for reference current-flow distribution. The variable mesh density is arranged to control mechanical flexibility, for example as illustrated and described with respect to the flexible circuit structures 100, 200 of FIGS. 1 and 2.

Referring to FIG. 5, a next step generally designated by the reference character 500 of the fabrication sequence is shown to sputter coat a very thin copper layer or sputter coating 502 over an entire mesh surface of the meshed reference plane 402 of the fabrication sequence is shown. The sputter coating 502 has a thickness of around 1 micrometer of copper, without any impact on mechanical flexibility.

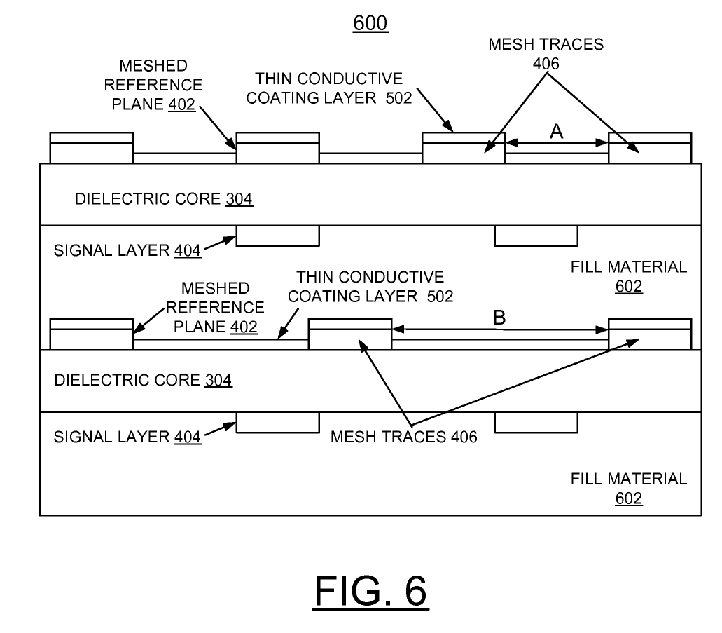

Referring to FIG. 6 a next step generally designated by the reference character 600 of the fabrication sequence is shown where other various sub-layers are then laminated together with respective layers of fill material 602 to form a flexible circuit structure, such as the flexible circuit structures 100, 200 of FIGS. 1 and 2. As shown, different mesh pitches for the two different meshed reference planes 402 are provided as indicated by a respective one of arrows labeled A and B, without resulting in significant impedance discontinuities for the signal layer 402 between these variable meshed reference power planes.

While the present invention has been described with reference to the details of the embodiments of the invention shown in the drawing, these details are not intended to limit the scope of the invention as claimed in the appended claims.

What is claimed is:

1. A method for implementing flexible circuits of various electronic packages and circuit applications comprising the steps of:
forming a meshed reference plane including a variable mesh pitch; said variable mesh pitch being arranged for control of mechanical flexibility;
forming a signal layer including a dielectric core separating said signal layer from said variable pitch meshed reference plane; and
applying an electrically conductive coating covering a surface of said variable pitch meshed reference plane for yielding substantially constant signal impedance for the signal layer.

2. A method for implementing flexible circuits as recited in claim 1 wherein forming said meshed reference plane includes forming a dense mesh path for carrying high current.

3. A method for implementing flexible circuits as recited in claim 2 further includes forming a less dense mesh around said dense mesh path for small current flow providing enhanced flexibility for the flexible circuit.

4. A method for implementing flexible circuits as recited in claim 1 wherein forming said meshed reference plane includes forming a wide mesh pitch generally centrally located.

5. A method for implementing flexible circuits as recited in claim 1 further includes forming an increasing mesh pitch from said wide mesh pitch to control of mechanical flexibility, providing enhanced flexibility near the center of the flexible circuit spaced apart from an associated connector.

6. A method for implementing flexible circuits as recited in claim 1 wherein applying said electrically conductive coating covering a surface of said variable pitch meshed reference plane for yielding substantially constant signal impedance for the signal layer includes depositing a thin electrically conductive coating covering a surface of said variable pitch meshed reference plane without affecting mechanical flexibility of said variable pitch meshed reference plane.

7. A method for implementing flexible circuits as recited in claim 1 wherein applying said electrically conductive coating covering a surface of said variable pitch meshed reference plane for yielding substantially constant signal impedance for the signal layer includes forming a copper thin film on said variable pitch meshed reference plane.

8. A method for implementing flexible circuits as recited in claim 1 wherein applying said electrically conductive coating covering a surface of said variable pitch meshed reference plane for yielding substantially constant signal impedance for the signal layer includes depositing said electrically conductive coating having a thickness of about one micrometer (10⁻⁶ meter).

9. A method for implementing flexible circuits as recited in claim 1 wherein applying said electrically conductive coating covering a surface of said variable pitch meshed reference plane for yielding substantially constant signal impedance for the signal layer includes depositing a copper coating having a thickness of about one micrometer (10⁻⁶ meter).

10. A structure for implementing flexible circuits comprising:
a variable pitch mesh reference plane including a variable mesh pitch;
said variable mesh pitch being arranged for control of mechanical flexibility;
a signal layer;
a dielectric core separating said signal layer from said variable pitch meshed reference plane; and
an electrically conductive coating covering an entire surface of said variable pitch meshed reference plane, said electrically conductive coating yielding substantially constant signal impedance for said signal layer.

11. The structure for implementing flexible circuits as recited in claim 10 wherein said electrically conductive coating includes a thin electrically conductive coating substantially without affecting mechanical flexibility of said variable pitch mesh reference plane.

12. The structure for implementing flexible circuits as recited in claim 10 wherein said electrically conductive coating includes a copper thin film covering said entire surface of said variable pitch meshed reference plane.

13. The structure for implementing flexible circuits as recited in claim 10 wherein said electrically conductive coating includes an electrically conductive coating having a thickness of about one micrometer (10⁻⁶ meter).

14. The structure for implementing flexible circuits as recited in claim 13 wherein said electrically conductive coating is formed of copper.

15. The structure for implementing flexible circuits as recited in claim 10 wherein said variable pitch meshed reference plane includes a dense mesh path for carrying high current.

16. The structure for implementing flexible circuits as recited in claim 15 wherein said variable pitch meshed reference plane further includes a less dense mesh around said dense mesh path for small current flow providing enhanced flexibility for the flexible circuit.

17. The structure for implementing flexible circuits as recited in claim 10 wherein said variable pitch meshed reference plane includes a first generally centrally located area of a wide mesh pitch.

18. The structure for implementing flexible circuits as recited in claim 17 wherein said variable pitch meshed reference plane further includes an increasing mesh pitch extending outwardly from said wide mesh pitch to control of mechanical flexibility, providing enhanced flexibility near the center of the flexible circuit spaced apart from an associated connector.

19. The structure for implementing flexible circuits as recited in claim 10 includes a plurality of variable pitch mesh reference planes, and wherein said plurality of variable pitch mesh reference planes include different mesh pitches.

20. The structure for implementing flexible circuits as recited in claim 19 wherein one of said plurality of variable pitch mesh reference planes carries a higher current than an adjacent power plane and includes a more dense mesh for carrying high current than said adjacent power plane.
